(19) United States
(12) Patent Application Publication
(10) Pub. No.: US 2025/0349524 A1
(43) Pub. Date: Nov. 13, 2025

(54) PLASMA PROCESSING APPARATUS AND PLASMA ETCHING METHOD

(71) Applicant: Tokyo Electron Limited, Tokyo (JP)

(72) Inventor: Naoki MATSUMOTO, Miyagi (JP)

(73) Assignee: Tokyo Electron Limited, Tokyo (JP)

(21) Appl. No.: 19/278,865

(22) Filed: Jul. 24, 2025

Related U.S. Application Data
(63) Continuation of application No. PCT/JP2024/002218, filed on Jan. 25, 2024.

(30) Foreign Application Priority Data
Feb. 3, 2023 (JP) 2023-015672

(51) Int. Cl. H01J 37/32

(52) U.S. Cl. CPC H01J 37/32724; H01J 37/3211; H01J 37/32119; H01J 37/32853; H01J 2237/3341

(57) ABSTRACT

Provided is a plasma processing apparatus including: a chamber, a substrate support disposed in the chamber and including a coolant passage, a dielectric window disposed above the substrate support, an antenna, an RF power source to supply an RF signal to the antenna, a coolant supply to supply a coolant maintained at a first temperature to the coolant passage, at least one heater disposed in the substrate support, a heater power source to supply power to the at least one heater, at least one light source, a temperature monitor to monitor a temperature of the substrate on the substrate support, and a controller to control, the temperature monitor, the coolant supply, the heater power source, and/or the at least one light source.

### CROSS-REFERENCE TO RELATED APPLICATIONS

This application is a bypass continuation application of international application No. PCT/JP2024/002218 having an international filing date of Jan. 25, 2024 and designating the United States, the international application being based upon and claiming the benefit of priority from Japanese Patent Application No. 2023-015672, filed on Feb. 3, 2023, the entire contents of each are incorporated herein by reference.

### TECHNICAL FIELD

The present disclosure relates to a plasma processing apparatus and a plasma etching method.

### BACKGROUND

PTL 1 discloses that in a step of etching a silicon-containing film as a film to be etched formed at a front surface of a substrate, an etching rate of the silicon-containing film is increased by maintaining the substrate at a low temperature.

PTL 2 discloses that in a step of etching a silicon-containing film formed at a front surface of a substrate while maintaining the substrate at a low temperature, an electromagnetic wave is temporarily emitted to heat the substrate and sublimate reaction products.

### CITATION LIST

### Patent Documents

PTL 1: JP2021-153170A
PTL 2: JP2020-115498A

### SUMMARY

According to a technique of the present disclosure, a temperature of a surface layer of a substrate is increased during plasma generation in a plasma processing apparatus to efficiently remove a by-product.

An aspect of the present disclosure provides a plasma processing apparatus including: a chamber, a substrate support disposed in the chamber and including a coolant passage, a dielectric window disposed above the substrate support, an antenna disposed above the dielectric window, an RF power source configured to supply an RF signal to the antenna in order to generate plasma in the chamber, a coolant supply configured to supply a coolant maintained at a first temperature to the coolant passage, at least one heater disposed in the substrate support, a heater power source configured to supply power to the at least one heater, at least one light source configured to temporarily and periodically irradiate a substrate on the substrate support with light to heat the substrate while the plasma is generated in the chamber and while the coolant maintained at the first temperature is supplied to the coolant passage, a temperature monitor configured to monitor a temperature of the substrate on the substrate support, and a controller configured to control, based on an output from the temperature monitor, the coolant supply, the heater power source, and/or the at least one light source to adjust the first temperature of the coolant, the power supplied to the at least one heater, and/or an intensity of the light with which the substrate on the substrate support is irradiated.

According to the present disclosure, a temperature of a surface layer of a substrate can be increased during plasma generation in a plasma processing apparatus to efficiently remove a by-product.

### BRIEF DESCRIPTION OF DRAWINGS

FIG. 1 is a diagram illustrating a configuration example of a plasma processing system according to an embodiment.

FIG. 2 is a cross-sectional view illustrating a configuration example of a plasma processing apparatus according to the embodiment.

FIG. 3 is a cross-sectional view illustrating a configuration example of a light irradiator according to the embodiment.

FIG. 4 is a cross-sectional view illustrating a configuration example of the light irradiator according to the embodiment.

FIG. 5 is a cross-sectional view illustrating a configuration example of the light irradiator according to the embodiment.

FIG. 6 is a diagram schematically illustrating an optical interference system.

FIG. 7 is a diagram illustrating an example of light reflection at a front surface and a rear surface of a substrate in the optical interference system.

FIG. 8 is a cross-sectional view illustrating another configuration example of the plasma processing apparatus according to the embodiment.

FIG. 9 is a cross-sectional view illustrating an example of a positional relationship of the light irradiator in the other configuration example of the plasma processing apparatus according to the embodiment.

FIG. 10 is a cross-sectional view illustrating another configuration example of the plasma processing apparatus according to the embodiment.

FIG. 11 is a cross-sectional view illustrating an example of a positional relationship of the light irradiator in the other configuration example of the plasma processing apparatus according to the embodiment.

FIG. 12 is a flowchart illustrating a configuration example of a plasma etching method according to the embodiment.

FIG. 13 is a sequence chart illustrating a configuration example of the plasma etching method according to the embodiment.

### DETAILED DESCRIPTION

In a process for manufacturing a semiconductor device, for example, as disclosed in PTL 1, there is known a method of etching a silicon-containing film or the like formed at a front surface of a semiconductor wafer (hereinafter referred to as a “substrate”) using processing gas plasma. In the plasma etching step, there is known a method of maintaining the substrate at a low temperature of 0° C. or lower in order to improve an etching rate of the silicon-containing film.

According to this etching method, various by-products are generated due to a reaction between the silicon-containing film and the processing gas plasma. In a state where the substrate is maintained at a low temperature, volatility of such by-products may decrease and the by-products may remain on the substrate. When the by-products remain on the substrate, an etching defect such as etching shape deterioration or an etching stop due to clogging may occur.

In order to remove the by-products, it is conceivable to temporarily increase the temperature of the substrate to sublimate the by-products. In order to increase the temperature of the substrate, it is conceivable to use a method of adjusting a mixture ratio of a high-temperature coolant and a low-temperature coolant supplied to a substrate support that supports the substrate, or a method of adjusting a heater temperature. However, these methods for adjusting a temperature of the substrate support have poor responsiveness. In addition, since the temperature of the substrate is adjusted from a rear surface side of the substrate, the front surface of the substrate where the by-products adhere cannot be directly controlled.

In order to increase the temperature of the substrate, it is conceivable to heat the substrate by temporarily irradiating the substrate with an electromagnetic wave during the etching step, as disclosed in PTL 2. However, the method in PTL 2 has room for improvement in reducing a time required to cool the substrate to a process temperature after heating the entire substrate.

As a result of diligent studies by the inventors in consideration of the above problems, it has been found that the by-products can be sublimated by maintaining a portion other than a surface layer of the substrate at a low temperature and heating only the surface layer of the substrate. It is also conceived that, by maintaining the portion other than the surface layer of the substrate at a low temperature and heating only the surface layer of the substrate, the substrate can be cooled immediately after the by-products are removed to enable an immediate transition to a next process, which is advantageous in terms of productivity.

Therefore, in a technique according to the present disclosure, by irradiating a substrate with light in a state where a portion other than a surface layer of the substrate is maintained at a low temperature, a temperature of the surface layer of the substrate is increased, and a by-product can be efficiently removed.

Hereinafter, a configuration of a plasma processing apparatus according to the embodiment will be described with reference to the drawings. The same reference numerals will be given to elements having substantially the same functional configurations throughout the specification, and redundant description thereof will be omitted.

### <Plasma Processing System>

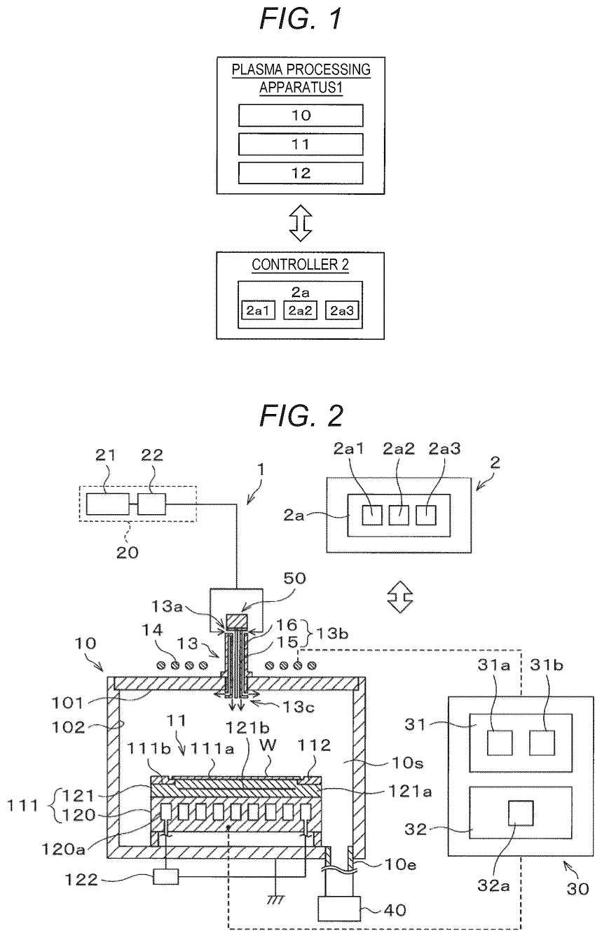

FIG. 1 is a diagram for explaining an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma generator 12 is configured to generate plasma from at least one processing gas supplied into the plasma processing space. The plasma formed in the plasma processing space may be inductively-coupled plasma (ICP), capacitively-coupled plasma (CCP), electron-cyclotron-resonance plasma (ECR plasma), Helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2al, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2al, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### First Embodiment

Hereinafter, an example of a configuration of the plasma processing apparatus 1 according to a first embodiment will be described with reference to FIG. 2. The plasma processing apparatus 1 according to the first embodiment is an inductively-coupled plasma processing apparatus.

The plasma processing apparatus 1 according to the first embodiment includes the plasma processing chamber 10, the gas supply 20, a power source 30, the exhaust system 40, and a light irradiator 50. The plasma processing chamber 10 includes a dielectric window 101. Further, the plasma processing apparatus 1 includes the substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, the sidewall 102 of the plasma processing chamber 10, and the substrate support 11. The plasma processing chamber 10 is grounded.

The substrate support 11 includes a main body 111 and a ring assembly 112. The main body 111 has a central region 111a, which supports a substrate W, and an annular region 1l1b, which supports the ring assembly 112. A wafer is an example of the substrate W. The annular region 1l1b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 120 and an electrostatic chuck 121. The base 120 includes a conductive member. The conductive member of the base 120 may function as a bias electrode. The electrostatic chuck 121 is disposed on the base 120. The electrostatic chuck 121 includes a ceramic member 121a and an electrostatic electrode 121b disposed in the ceramic member 121a. The ceramic member 121a has the central region 111a. In one embodiment, the ceramic member 121a also has the annular region 1l1b. Other members that surround the electrostatic chuck 121, such as an annular electrostatic chuck and an annular insulating member, may have the annular region 1l1b. In this case, the ring assembly 112 may be disposed on the annular electrostatic chuck or the annular insulating member, or may be disposed on both the electrostatic chuck 121 and the annular insulating member. At least one RF/DC electrode coupled to an RF power source 31 and/or a DC power source 32, which will be described later, may be disposed in the ceramic member 121a. In this case, at least one RF/DC electrode functions as the bias electrode. The conductive member of the base 120 and the at least one RF/DC electrode may function as a plurality of bias electrodes. The electrostatic electrode 121b may also function as a bias electrode. Accordingly, the substrate support 11 includes at least one bias electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may include a temperature control module configured to adjust at least one of the electrostatic chuck 121, the ring assembly 112, and the substrate W to a target temperature. The temperature control module may include a heater, a heat transfer medium, a flow path 120a, or a combination thereof. A heat transfer fluid, such as brine or gas, flows through the flow path 120a. In one embodiment, the flow path 120a is formed in the base 120, and one or a plurality of heaters are disposed in the ceramic member 121a of the electrostatic chuck 121. The substrate support 11 may further include a heat transfer gas supply configured to supply a heat transfer gas to a gap between a rear surface of the substrate W and the central region 111a.

In one embodiment, a chiller 122 (coolant supply) is provided as the heat transfer gas supply. The coolant supply is configured to supply a coolant as a heat transfer medium to the flow path 120a to maintain the substrate at the target temperature or lower during plasma generation. The target temperature is a temperature at which an etching rate of a silicon-containing film can be improved in a plasma etching step. As an example, this temperature is −20° C. In one embodiment, the chiller 122 is controlled to maintain the coolant supplied to the flow path 120a at −20° C. or lower. In one embodiment, the plasma processing apparatus 1 includes at least one heater disposed in the substrate support 11, and a heater power source configured to supply power to the at least one heater. In one embodiment, the substrate support 11 has a plurality of regions in a plan view, and the at least one heater includes a plurality of heaters disposed in the plurality of regions, respectively.

The gas introduction unit is configured to introduce at least one processing gas from the gas supply 20 into the plasma processing space 10s. In one embodiment, the gas introduction unit includes a center gas injector (CGI) 13. The center gas injector 13 is disposed above the substrate support 11 and attached to a center opening formed in the dielectric window 101. The center gas injector 13 is made of a dielectric such as ceramic or quartz, and has a substantially cylindrical shape. The center gas injector 13 has at least one gas supply port 13a, at least one gas flow path 13b, and at least one gas introduction port 13c.

The gas flow path 13b includes central flow paths 15 provided at positions that surround a housing 52 of the light irradiator 50 to be described later in a plan view, and side flow paths 16 provided at positions that surround a periphery of the central flow paths 15 in a plan view. Details of the configuration of the gas flow path 13b will be described later.

The processing gas supplied to the gas supply port 13a passes through the gas flow path 13b and is introduced into the plasma processing space 10s from the gas introduction port 13c. In one embodiment, the processing gas supplied to each central flow path 15 through the gas supply port 13a is injected downward from a plurality of gas introduction ports 13c. In addition, the processing gas supplied to the side flow path 16 through the gas supply port 13a is radially injected from the plurality of gas introduction ports 13c in directions perpendicular to a Z-axis around the Z-axis. The gas introduction unit may include one or a plurality of side gas injectors (SGI) attached to one or a plurality of openings formed in the sidewall 102, in addition to the center gas injector 13.

The gas supply 20 may include at least one gas source 21 and at least one flow rate controller 22. In one embodiment, the gas supply 20 is configured to supply at least one processing gas from the respective corresponding gas sources 21 to the center gas introduction unit through the respective corresponding flow rate controllers 22. Each flow rate controller 22 may include, for example, a mass flow controller or a pressure-controlled flow rate controller. The gas supply 20 may further include at least one flow rate modulating device that modulates or pulses the flow rate of the at least one processing gas.

The power source 30 includes the RF power source 31 coupled to the plasma processing chamber 10 via at least one impedance matching circuit. The RF power source 31 is configured to supply at least one RF signal (RF power) to the at least one bias electrode and the antenna 14. Accordingly, the plasma is formed from at least one processing gas supplied into the plasma processing space 10s. Accordingly, the RF power source 31 may function as at least a part of the plasma generator 12. Supplying the bias RF signal to at least one bias electrode can generate a bias potential in the substrate W to attract ions in the formed plasma to the substrate W.

In one embodiment, the RF power source 31 includes a first RF generator 31a and a second RF generator 31b. The first RF generator 31a is configured to be coupled to the antenna 14 through at least one impedance matching circuit so as to generate the source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one bias electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one bias electrode. In various embodiments, at least one of the source RF signal and the bias RF signal may be pulsed.

The power source 30 may include the DC power source 32 coupled to the plasma processing chamber 10. The DC power source 32 includes a bias DC generator 32a. In one embodiment, the bias DC generator 32a is connected to at least one bias electrode and configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform of a rectangle, a trapezoid, a triangle or a combination thereof. In one embodiment, a waveform generator for generating the sequence of voltage pulses from the DC signal is connected between the bias DC generator 32a and at least one bias electrode. Accordingly, the bias DC generator 32a and the waveform generator configure a voltage pulse generator. The voltage pulse may have a positive polarity or a negative polarity. Further, the sequence of the voltage pulses may include one or more positive voltage pulses and one or more negative voltage pulses in one cycle. The bias DC generator 32a may be provided in addition to the RF power source 31, or may be provided instead of the second RF generator 31b.

The antenna 14 includes one or more coils. In one embodiment, the antenna 14 may include an outer coil and an inner coil that are coaxially disposed (with central axes Z thereof overlapping each other). In this case, the RF power source 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

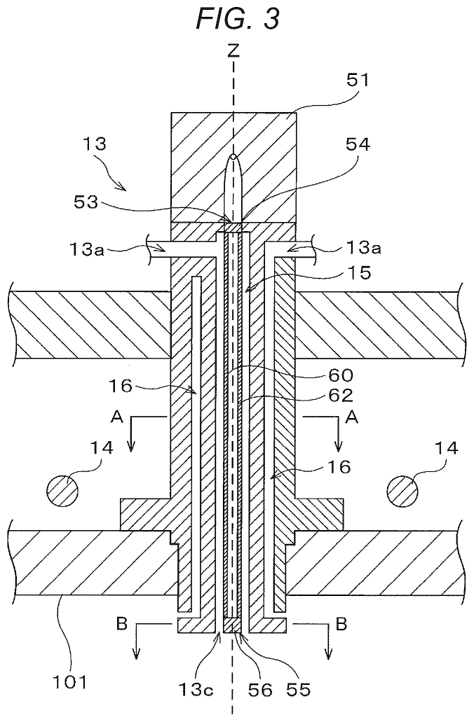

Hereinafter, an example of configurations of the light irradiator 50 and the center gas injector 13 will be described with reference to FIG. 3. The light irradiator 50 includes a vertical light source 51 (hereinafter, also referred to as the light source 51) and the housing 52 that transmits light emitted from the light source 51 to the plasma processing chamber 10. In the first embodiment, the housing 52 is provided at a position overlapping the central axis Z of the antenna 14. The vertical light source 51 is configured to temporarily and periodically irradiate the substrate W with light in order to heat the substrate W on the substrate support 11 while plasma is generated in the chamber 10 and while the coolant maintained at −20° C. or lower is supplied to the coolant passage 120a. The light from the vertical light source 51 is emitted in a vertical direction.

In one embodiment, the light source 51 emits light having a wavelength of 300 nm to 1,100 nm. As an example, such a light source 51 includes a halogen heater lamp. The halogen heater lamp can emit light having a wavelength of 300 nm to 1,100 nm. In addition, since electrical energy is converted into light with high efficiency to directly heat the material, thermal energy conversion efficiency is high.

In one embodiment, thermal energy conversion efficiency of 80% to 90% of input power can be obtained. In addition, since a tungsten filament is used as a heat source, the temperature can be increased in a short time, and responsiveness is high. It is also possible to reduce a heat dissipation loss. In addition, temperature adjustment by power control is easy, control can be performed to prevent excessive heating, and an energy loss can be reduced. In addition, since the heating is performed only when necessary and is turned off when unnecessary, it is possible to enable power reduction. In addition, the halogen lamp has a longer lifespan than a general light source using a filament and can emit light stably until an end of the lifespan. In addition, since non-contact heating is performed through the quartz window, there is an advantage that a heated object is not contaminated.

As another example, the light source 51 includes a flash lamp. As the flash lamp, a lamp having a configuration disclosed in JP2020-043180A can be used. The flash lamp is suitable for controlling pulsed irradiation to be described later. As still another example, the light source 51 includes a light emitting diode (LED). The LED can emit light with high energy efficiency and has a long lifespan.

The housing 52 includes a first window 54 at a first end 53 and a second window 56 at a second end 55. The light source 51 and the first end 53 of the central flow path 15 are connected through the first window 54. In addition, the plasma processing chamber 10 and the second end 55 of the housing 52 are connected through the second window 56.

The inside of the housing 52 is vacuum-sealed. In addition, a reflective wall 62 that reflects the light emitted from the light source 51 is formed at an inner wall 60 of the housing 52. As an example, the reflective wall 62 is formed by vapor-depositing a metal such as aluminum at a surface of the inner wall 60.

The first window 54 and the second window 56 are made of a material that transmits the light emitted from the light source 51. As an example, the first window and the second window may be a transparent material such as quartz (SiO₂), sapphire (Al₂O₃), or Y₂O₃. Quartz, sapphire, Y₂O₃, or the like have high transparency to light having a wavelength of 300 nm to 1,100 nm and can be used when the light source 51 emits light having a wavelength of 300 nm to 1,100 nm.

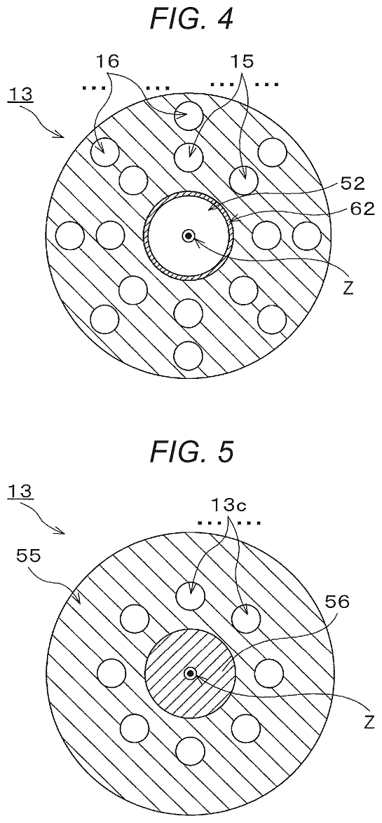

FIG. 4 is a cross-sectional view when the center gas injector 13 is viewed in a direction of an arrow at a position A-A in FIG. 3. In FIG. 4, a central axis of the housing 52 is provided to overlap the central axis Z of the antenna 14. A plurality of central flow paths 15 are provided at rotationally symmetrical positions to surround the housing 52. In addition, a plurality of side flow paths 16 are provided at rotationally symmetrical positions to surround the central flow paths 15.

FIG. 5 is a cross-sectional view when the center gas injector 13 is viewed in a direction of an arrow at a position B-B in FIG. 3. In FIG. 5, the second end 55 is provided with the second window 56. A plurality of gas introduction ports 13c through which the processing gas is supplied to the central flow paths 15 passes are provided around the second window 56. The plurality of gas introduction ports 13c are provided at rotationally symmetrical positions to surround the second window 56.

According to the light irradiator 50 having the configuration described above, the light emitted from the light source 51 enters the housing 52 through the first window 54, travels while being reflected off the reflective wall 62 in the housing 52, and is transmitted through the second window 56 to the plasma processing chamber 10. The light transmitted to the plasma processing chamber 10 is emitted to a front surface of the substrate W placed on the substrate support 11.

In one embodiment, the second window 56 has a concave lens shape. By forming the second window 56 in a concave lens shape, the light traveling through the central flow path 15 can be refracted from a direction toward a central portion of the substrate W to a direction toward a peripheral portion of the substrate W. Accordingly, the light can be radially diverged by the second window 56, and the entire substrate W may be irradiated with the light. In one embodiment, the second window 56 is a hemispherical lens. By forming the second window 56 as a hemispherical lens, the light traveling through the central flow path 15 can be refracted from the direction toward the central portion of the substrate W to the direction toward the peripheral portion of the substrate W. Accordingly, the light can be radially diverged by the second window 56, and the entire substrate W may be irradiated with the light.

In one embodiment, the plasma processing apparatus 1 includes a temperature monitor configured to monitor a temperature of the substrate W on the substrate support 11. The temperature monitor includes an optical interference system 100. The substrate W in this case is, for example, a wafer made of silicon. An electromagnetic wave generated by a light source (monitor light source) is, for example, light (monitor light).

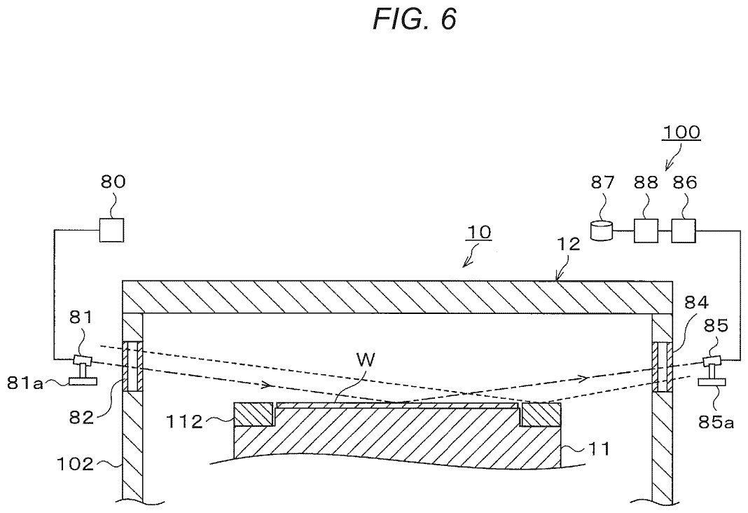

FIG. 6 is a diagram schematically illustrating the optical interference system 100 according to the exemplary embodiment. As shown in FIG. 6, the optical interference system 100 is applied to the plasma processing apparatus 1. At least one window, in the embodiment, a first window 82 and a second window 84 are provided at the sidewall 102 of the chamber 10 of the plasma processing apparatus 1. The first window 82 and the second window 84 are provided at positions facing each other on the sidewall 102 of the chamber 10. That is, the first window 82 is disposed opposite to the second window 84. The optical interference system 100 emits and receives light through the first window 82 and the second window 84, and measures the temperature of the substrate W on the substrate support 11.

The optical interference system 100 includes a light source 80 that is an example of the monitor light source, a focuser 81 that is an example of an emitter, a collimator 85 that is an example of a light receiver, a spectrometer 86, a storage 87, and a control device 88.

The light source 80 is configured to emit light transmissible through the substrate W on the substrate support 11 and is either a low-coherence light source or a wavelength-tunable light source. The low-coherence light source is a light source whose generated light has a coherence length (interference distance) on the order of micrometers or less. For example, the low-coherence light source is a light source having a coherence length of several tens of m. As an example, the low-coherence light source is a super luminescent diode (SLD). The wavelength-tunable light source is a light source that can freely change a wavelength of generated light.

The focuser 81 is provided outside the chamber 10 and is configured to emit the light (monitoring light) generated by the light source 80 toward the substrate W on the substrate support 11. The focuser 81 is connected to the light source 80 through an optical fiber or the like. The light generated by the light source 80 propagates to the focuser 81 through the optical fiber. The focuser 81 emits the light toward the substrate W on the substrate support 11 through the first window 82 (see a long-dashed dotted line in the figure). The focuser 81 is disposed such that the light reflected by the front surface and the rear surface of the substrate W on the substrate support 11 is incident on the second window 84. The focuser 81 may be a collimator.

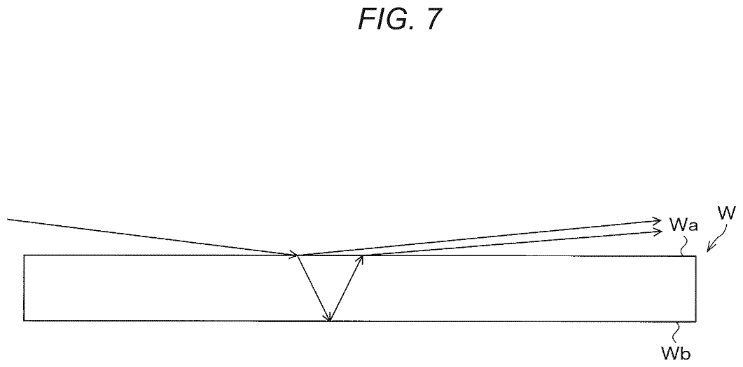

The collimator 85 is provided outside the chamber 10 and is configured to receive the reflected light from the substrate W. The collimator 85 is disposed on a side opposite to the focuser 81 with the substrate W interposed therebetween. The collimator 85 receives the reflected light from the substrate W on the substrate support 11 through the second window 84. The collimator 85 is connected to the spectrometer 86 through an optical fiber or the like. The collimator 85 receives the reflected light and propagates the light to the spectrometer 86 through the optical fiber or the like. The collimator 85 may be a focuser. FIG. 7 is a diagram illustrating an example of reflection at a front surface Wa and a rear surface Wb of the substrate W. As shown in FIG. 7, the light incident on the substrate W is reflected by the front surface Wa of the substrate W and is also reflected by the rear surface Wb of the substrate W. The reflected light becomes interference light that includes reflected light from each of two parallel reflective surfaces.

Referring back to FIG. 6, the spectrometer 86 is configured to detect a spectrum of the reflected light received by the collimator 85. The spectrometer 86 includes, for example, a spectroscopic mechanism and a detection unit. The spectroscopic mechanism disperses light at a predetermined dispersion angle for each wavelength. An example of the spectroscopic mechanism is a diffraction grating. The detection unit detects the light dispersed by the spectroscopic mechanism. An example of the detection unit is a charge coupled device (CCD). The number of elements in the CCD corresponds to a sampling number.

The detection unit detects a reflected light intensity for each wavelength as the spectrum. The spectrum may be a reflectance curve representing a relationship between a wavelength and a reflectance. When the reflectance curve is detected, the temperature of the substrate W is calculated based on a correlation.

The storage 87 is configured to store a relationship between the reflectance curve and the temperature in advance. The relationship between the reflectance curve and the temperature is data to be used as a reference and is obtained in advance. The storage 87 may store the relationship between the reflectance curve and the temperature for each material.

The control device 88 is connected to the spectrometer 86 and the storage 87. The control device 88 is configured to calculate the temperature of the substrate W based on the reflectance curve detected by the spectrometer 86 and the relationship stored in the storage 87. The control device 88 may be a computer including a processor, a storage, an input device, a display device, and the like. In one embodiment, the control device 88 is provided in the controller 2.

Accordingly, the temperature monitor (optical interference system 100) includes the monitor light source (light source 80), the emitter (focuser 81), and the light receiver (collimator 85). The monitor light source (light source 80) is configured to emit the electromagnetic wave transmissible through the substrate W on the substrate support 11. The emitter (the focuser 81) is configured to obliquely emit the electromagnetic wave generated by the monitor light source (the light source 80) to the substrate W on the substrate support 11. The light receiver (collimator 85) is disposed on a side opposite to the emitter (focuser 81) and is configured to receive a reflected wave reflected by the front surface and the rear surface of the substrate W on the substrate support 11. The controller 2 is configured to determine the temperature of substrate W on the substrate support 11 based on the reflected wave incident on the light receiver (collimator 85).

The optical interference system 100 may use either a spectroscopic method or a wavelength sweeping method. The spectroscopic method is a method in which a broadband light source such as an SLD or amplified spontaneous emission (ASE) is used, and light is dispersed with a grating or the like to acquire a spectrum using a charge coupled device (CCD) array or the like. The wavelength sweeping method is a method of sweeping a wavelength of output light using a narrowband light source that can control the wavelength of the output light, and receiving the light by a photodiode or the like.

The optical interference system 100 may include a mechanism for adjusting an optical axis. For example, the focuser 81 may be supported by a first adjustment mechanism 81a. The first adjustment mechanism 81a is a mechanism that can adjust an emission direction of the focuser 81. The first adjustment mechanism 81a is, for example, a three-axis stage movable in an X-axis, a Y-axis, and a Z-axis. The collimator 85 may be supported by a second adjustment mechanism 81b. The second adjustment mechanism 81b may have the same configuration as the first adjustment mechanism 81a.

In one embodiment, the controller 2 is configured to control, based on an output from the temperature monitor, the coolant supply, the heater power source, and/or at least one light source 51 to adjust a first temperature of the coolant, power supplied to at least one heater, and/or an intensity of light with which the substrate W on the substrate support 11 is irradiated. In one embodiment, the controller 2 is configured to control, based on the output from the temperature monitor, the heater power source to adjust power supplied to each of a plurality of heaters in order to correct temperature non-uniformity of the substrate W on the substrate support 11 caused by light irradiation.

The temperature monitor in the first embodiment has been described above, and a temperature monitor having the same configuration may be provided in other embodiments to be described later.

According to the plasma processing apparatus 1 of the first embodiment, the light irradiator 50 is provided above the substrate W at a position opposite to the substrate W, and thus an average distance between the second window 56 and the substrate W in the light irradiator 50 can be shortened. Accordingly, it is possible to efficiently irradiate the substrate W with the light emitted from the light source 51. In addition, since the light irradiator 50 is disposed to overlap the central axis Z of the antenna, a distance between the second window 56 in the light irradiator 50 and the central portion or the peripheral portion of the substrate W becomes uniform. Accordingly, it is possible to uniformly irradiate the substrate W with light.

In the inductively-coupled plasma processing apparatus 1, an RF signal is supplied to the antenna 14 to induce an electromagnetic field, thereby generating plasma. Therefore, disposing a configuration other than the antenna 14 above the plasma processing chamber 10 (above the dielectric window 101) where the antenna 14 is disposed may hinder the induction of the electromagnetic field, which may hinder generation or maintenance of plasma.

In view of such a problem, the inventors have diligently studied and found that the problem can be solved by configuring the light irradiator 50 as described above. That is, since the housing 52 in the light irradiator 50 is disposed to overlap the central axis Z of the antenna 14, it is possible to reduce an influence on the electromagnetic field caused by installation of the light irradiator 50.

The light with which the front surface of the substrate W is irradiated is absorbed by the material constituting the substrate W, and a temperature of a region containing the material increases. Specifically, absorption of light refers to a state where amplitude of molecular vibration in a substance (for example, silicon) is promoted and high thermal energy is maintained when a vibrational frequency of incident light matches an intrinsic vibrational frequency that depends on an interatomic bonding force and mass. This state can be referred to as a state where light is absorbed and heating occurs. As an example, in a case where a film to be etched is a silicon-containing film, silicon has bandgap energy of about 1.1 eV, absorbs well near-infrared light or visible light having a wavelength shorter than 1,100 nm, and hardly absorbs infrared light having a wavelength longer than 1,100 nm. Therefore, when the light source 51 emits light having a wavelength of 300 nm to 1,100 nm, a silicon-containing film containing Si, SiN, or the like, which has high absorbance for such light, absorbs the light, and a temperature of a region containing the material on the substrate W increases. Since tungsten also absorbs light having a wavelength of 300 nm to 1,100 nm, a temperature of a region containing tungsten on the substrate W increases.

When the temperature of the substrate W increases, heat thereof is conducted to a by-product generated by plasma etching and adhering to the substrate, and the by-product is sublimated. In addition, the temperature of the substrate W increases, and thus an etching reaction is promoted.

In the plasma etching step, when the film to be etched is a silicon-containing film such as a Si film, a SiO₂ film, or a SiN film, ammonium fluorosilicate (AFS: (NH₄)2SiF₆), CO, SiF₄, SiH₄, NH₃, or SiH₄ may be generated as by-products. In a state where the temperature of the substrate W is maintained at a low temperature (for example, −20° C.), SiH₄ or AFS among the by-products may adhere to the front surface of the substrate W as a by-product.

A temperature at which the by-product can be sublimated is, for example, 100° C. or higher. As an example, the by-product sublimated into a gas is exhausted to the outside of the plasma processing chamber 10 by the exhaust system 40.

### Second Embodiment

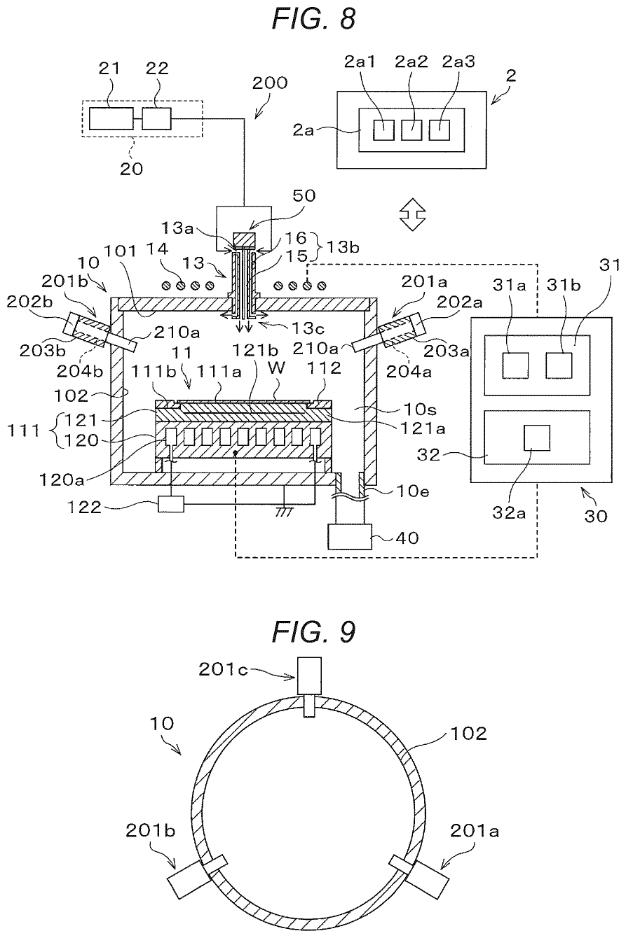

Hereinafter, an example of configurations of first to third light irradiators 201a to 201c (hereinafter, may be referred to as a light irradiator 201 collectively) in a plasma processing apparatus 200 according to a second embodiment will be described with reference to FIGS. 8 and 9. FIG. 8 is a cross-sectional view illustrating a configuration example of the plasma processing apparatus 200. FIG. 9 is a diagram illustrating an example of a positional relationship of the light irradiator when the plasma processing apparatus 200 is viewed from above. The plasma processing apparatus 200 according to the second embodiment is an inductively-coupled plasma processing apparatus, has the same configuration as the plasma processing apparatus 1 according to the first embodiment except for the configurations of the first to third light irradiators 201a to 201c, and exhibits the same functions and effects.

The first light irradiator 201a, the second light irradiator 201b, and the third light irradiator 201c include, respectively, a first oblique light source 202a, a second oblique light source 202b, and a third oblique light source 202c (hereinafter, may be referred to as an oblique light source 202 collectively). Accordingly, the plasma processing apparatus 200 includes at least one light source. The at least one light source includes the vertical light source 51 and the plurality of oblique light sources 202a, 202b, and 202c. The plurality of oblique light sources 202a, 202b, and 202c are arranged in a peripheral direction along the sidewall 102 of the plasma processing chamber 10. In one embodiment, the plurality of oblique light sources 202a, 202b, and 202c are arranged at equal intervals in the peripheral direction. The plurality of oblique light sources 202a, 202b, and 202c are configured to temporarily and periodically irradiate the substrate W with light in order to heat the substrate W on the substrate support 11 while plasma is generated in the chamber 10 and while the coolant maintained at −20° C. or lower is supplied to a coolant passage 120a. Light from each of the plurality of oblique light sources 202a, 202b, and 202c is emitted in an oblique direction. The first light irradiator 201a includes the first light source 202a and a first housing 203a that transmits light emitted from the first light source 202a to the plasma processing chamber 10. Similarly, the second light irradiator 201b includes the second light source 202b and a second housing 203b, and the third light irradiator 201c includes the third light source 202c and a third housing 203c. For example, the first housing 203a also has a first end connected to the first light source 202a and a second end connected to a window 210a provided at the sidewall 102 of the plasma processing chamber 10. A first reflective wall 204a that reflects the light emitted from the first light source 202a is formed at an inner wall of the first housing 203a. As an example, the first reflective wall 204a is formed by vapor-depositing a metal such as aluminum at a surface of the inner wall. The second housing 203b and the third housing 203c are similarly configured, with the second light irradiator 201b having a second light source 202b, a second reflective wall 204b and window 210a and the third housing having a third reflective wall.

In the second embodiment, the plurality of oblique light sources 202a, 202b, and 202c may be provided at rotationally symmetrical positions in a plan view of the plasma processing chamber 10.

According to the light irradiator 201 a/201b/201c having the configuration described above, the light emitted from the oblique light source 202a/202b enters the housing 203a/203b, travels while being reflected off the reflective wall 204a/204b in the housing 203, and is transmitted through the window 210 to the plasma processing chamber 10. The light transmitted to the plasma processing chamber 10 is emitted to the front surface of the substrate W placed on the substrate support 11.

As the oblique light source 202, the halogen heater lamp, the flash lamp, or the LED described in the first embodiment can be used.

### Third Embodiment

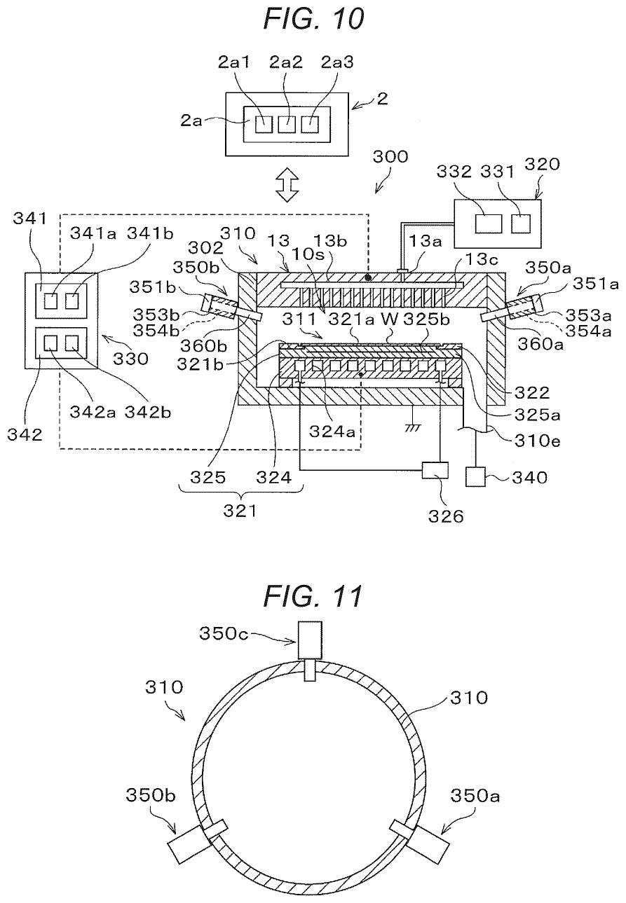

Hereinafter, an example of a configuration of a plasma processing apparatus 300 according to a third embodiment will be described with reference to FIGS. 10 and 11. The plasma processing apparatus 300 according to the third embodiment is a capacitively-coupled plasma processing apparatus. FIG. 10 is a cross-sectional view illustrating a configuration example of the plasma processing apparatus 300. FIG. 11 is a diagram illustrating an example of a positional relationship of a light irradiator 350 when the plasma processing apparatus 300 is viewed from above.

The capacitively-coupled plasma processing apparatus 300 includes a plasma processing chamber 310, a gas supply 320, a power source 330, an exhaust system 340, and a plurality of light irradiators 350a to 350c (hereinafter, may be referred to as a light irradiator 350). The plasma processing apparatus 300 also includes a substrate support 311 and a gas introduction unit. The gas introduction unit is configured to introduce at least one processing gas into the plasma processing chamber 310. The gas introduction unit includes a shower head 313. The substrate support 311 is disposed in the plasma processing chamber 310. The shower head 313 is disposed above the substrate support 311. In one embodiment, the shower head 313 constitutes at least a portion of a ceiling portion of the plasma processing chamber 310. The plasma processing chamber 310 has a plasma processing space 310s defined by the shower head 313, a sidewall 312 of the plasma processing chamber 310, and the substrate support 311. The plasma processing chamber 310 is grounded. The shower head 313 and the substrate support 311 are electrically insulated from a housing of the plasma processing chamber 310.

The substrate support 311 includes a main body 321 and a ring assembly 322. The main body 321 has a central region 321a for supporting the substrate W and an annular region 321b for supporting the ring assembly 322. The annular region 321b of the main body 321 surrounds the central region 321a of the main body 321 in a plan view. The substrate W is disposed on the central region 321a of the main body 321, and the ring assembly 322 is disposed on the annular region 321b of the main body 321 to surround the substrate W on the central region 321a of the main body 321. Accordingly, the central region 321a is also called a substrate support surface for supporting the substrate W, and the annular region 321b is also called a ring support surface for supporting the ring assembly 322.

In one embodiment, the main body 321 includes a base 324 and an electrostatic chuck 325. The base 324 includes a conductive member. The conductive member of the base 324 may function as a lower electrode. The electrostatic chuck 325 is disposed on the base 324. The electrostatic chuck 325 includes a ceramic member 325a and an electrostatic electrode 325b disposed in the ceramic member 325a. The ceramic member 325a has the central region 321a. In one embodiment, the ceramic member 325a also has the annular region 321b. Other members that surround the electrostatic chuck 325, such as an annular electrostatic chuck and an annular insulating member, may have the annular region 321b. In this case, the ring assembly 322 may be disposed on the annular electrostatic chuck or the annular insulating member, or may be disposed on both the electrostatic chuck 325 and the annular insulating member. At least one RF/DC electrode coupled to an RF power source 341 and/or a DC power source 342, which will be described later, may be disposed in the ceramic member 325a. In this case, the at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 324 and the at least one RF/DC electrode may function as a plurality of lower electrodes. The electrostatic electrode 325b may also function as a lower electrode. Accordingly, the substrate support 311 includes at least one lower electrode.

The ring assembly 322 includes one or a plurality of annular members. In one embodiment, the one or more annular members include one or more edge rings and at least one cover ring. The edge ring is made of an electrically conductive material or an insulating material, and the cover ring is made of an insulating material.

The substrate support 311 may include a temperature control module configured to adjust at least one of the electrostatic chuck 325, the ring assembly 322, and the substrate W to a target temperature. The temperature control module may include a heater, a heat transfer medium, a flow path 324a, or a combination thereof. A heat transfer fluid, such as brine or gas, flows through the flow path 324a. In one embodiment, the flow path 324a is formed in the base 324, and one or a plurality of heaters are disposed in the ceramic member 325a of the electrostatic chuck 325. The substrate support 311 may also include a heat transfer gas supply configured to supply a heat transfer gas to a gap between the rear surface of the substrate W and the central region 321a.

In one embodiment, a chiller 326 (coolant supply) is provided as the heat transfer gas supply. The coolant supply is configured to supply a coolant as a heat transfer medium to the flow path 324a to maintain the substrate at the target temperature or lower during plasma generation. The target temperature is a temperature at which an etching rate of a silicon-containing film can be improved in a plasma etching step. As an example, this temperature is −20° C. In one embodiment, the chiller 326 is controlled to maintain the coolant supplied to the flow path 120a at −20° C. or lower.

The shower head 313 is configured to introduce at least one processing gas from the gas supply 320 into the plasma processing space 310s. The shower head 313 includes at least one gas supply port 313a, at least one gas diffusion chamber 313b, and a plurality of gas introduction ports 313c. The processing gas supplied to the gas supply port 313a passes through the gas diffusion chamber 313b and is introduced into the plasma processing space 310s from the plurality of gas introduction ports 313c. The shower head 313 includes at least one upper electrode. The gas introduction unit may include, in addition to the shower head 313, one or a plurality of side gas injectors (SGI) that are attached to one or a plurality of openings formed in the sidewall 312.

The gas supply 320 may include at least one gas source 331 and at least one flow rate controller 332. In one embodiment, the gas supply 320 is configured to supply at least one processing gas from each corresponding gas source 331 to the shower head 313 via each corresponding flow rate controller 332. Each flow rate controller 332 may include, for example, a mass flow controller or a pressure-controlled flow rate controller. Further, the gas supply 320 may include at least one flow rate modulation device that modulates or pulses a flow rate of the at least one processing gas.

The power source 330 includes the RF power source 341 coupled to the plasma processing chamber 310 via at least one impedance matching circuit. The RF power source 341 is configured to supply at least one RF signal (RF power) to at least one lower electrode and/or at least one upper electrode. Accordingly, plasma is formed from the at least one processing gas supplied to the plasma processing space 310s. Accordingly, the RF power source 341 may function as at least a part of the plasma generator 12. Supplying the bias RF signal to at least one lower electrode can generate a bias potential in the substrate W to attract an ionic component in the formed plasma to the substrate W.

In one embodiment, the RF power source 341 includes a first RF generator 341a and a second RF generator 341b. The first RF generator 341a is coupled to at least one lower electrode and/or at least one upper electrode via the at least one impedance matching circuit, and is configured to generate a plasma generation source RF signal (source RF power). In one embodiment, the source RF signal has a frequency within a range from 10 MHz to 150 MHz. In one embodiment, the first RF generator 341a may be configured to generate a plurality of source RF signals having different frequencies. The generated one or more source RF signals are supplied to at least one lower electrode and/or at least one upper electrode.

The second RF generator 341b is coupled to the at least one lower electrode via the at least one impedance matching circuit and is configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 341b may be configured to generate a plurality of bias RF signals having different frequencies. The generated one or more bias RF signals are supplied to at least one lower electrode. In various embodiments, at least one of the source RF signal and the bias RF signal may be pulsed.

The power source 330 may include the DC power source 342 coupled to the plasma processing chamber 310. The DC power source 342 includes a first DC generator 342a and a second DC generator 342b. In one embodiment, the first DC generator 342a is connected to at least one lower electrode and is configured to generate a first DC signal. The generated first DC signal is applied to the at least one lower electrode. In one embodiment, the second DC generator 342b is connected to at least one upper electrode and is configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator for generating the sequence of voltage pulses from a DC signal is connected between the first DC generator 342a and at least one lower electrode. Accordingly, the first DC generator 342a and the waveform generator form a voltage pulse generator. When the second DC generator 342b and the waveform generator form the voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 342a and 342b may be provided in addition to the RF power source 341, and the first DC generator 342a may be provided instead of the second RF generator 341b.

The exhaust system 340 may be connected, for example, to a gas exhaust port 310e disposed at a bottom of the plasma processing chamber 310. The exhaust system 340 may include a pressure adjusting valve and a vacuum pump. The pressure adjusting valve adjusts a pressure in the plasma processing space 310s. The vacuum pump may include a turbo molecular pump, a dry pump, or a combination thereof.

The first light irradiator 350a, the second light irradiator 350b, and the third light irradiator 350c include, respectively, a first oblique light source 351a, a second oblique light source 351b, and a third oblique light source 351c (hereinafter, may be referred to as an oblique light source 351 collectively). Accordingly, the plasma processing apparatus 300 includes the plurality of oblique light sources 351a, 351b, and 351c. The plurality of oblique light sources 351a, 351b, and 351c are arranged in a peripheral direction along the sidewall 312 of the plasma processing chamber 310. In one embodiment, the plurality of oblique light sources 351a, 351b, and 351c are arranged at equal intervals in the peripheral direction. The plurality of oblique light sources 351a, 351b, and 351c are configured to temporarily and periodically irradiate the substrate W with light in order to heat the substrate W on the substrate support 311 while plasma is generated in the chamber 310 and while the coolant maintained at −20° C. or lower is supplied to the coolant passage 324a. Light from each of the plurality of oblique light sources 351a, 351b, and 351c is emitted in an oblique direction. The first light irradiator 350a includes the first light source 351a and a first housing 353a that transmits light emitted from the first light source 351a to the plasma processing chamber 310. Similarly, the second light irradiator 350b includes the second light source 351b and a second housing 353b, and the third light irradiator 350c includes the third light source 351c and a third housing 353c. For example, the first housing 353a also has a first end connected to the first light source 351a and a second end connected to a window 360a provided at the sidewall 312 of the plasma processing chamber 310. A first reflective wall 354a that reflects the light emitted from the first light source 351a is formed at an inner wall of the first housing 353a. As an example, the first reflective wall 354a is formed by vapor-depositing a metal such as aluminum at a surface of the inner wall. The second housing 353b and the third housing 353c are similarly configured, with the second light irradiator 350b having a second light source 351b, a second reflective wall 354b and window 360b.

In the second embodiment, the plurality of oblique light sources 351a, 351b, and 351c may be provided at rotationally symmetrical positions in a plan view of the plasma processing chamber 310.

As the oblique light source 351, the halogen heater lamp, the flash lamp, or the LED described in the first embodiment can be used.

According to the light irradiator 350a/350b/350c having the configuration described above, the light emitted from the oblique light source 351a/351b enters the housing 353a/353b, travels while being reflected off the reflective wall 354a/354b in the housing 353a/353b, and is transmitted through the window 360a/360b to the plasma processing chamber 310. The light transmitted to the plasma processing chamber 310 is emitted to the front surface of the substrate W placed on the substrate support 311.

### <Plasma Etching Method>

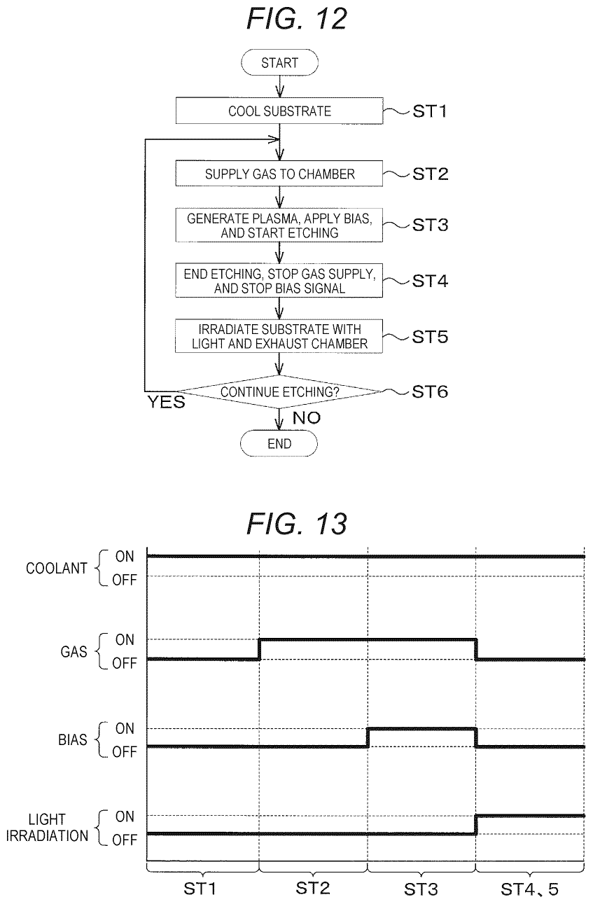

Next, a plasma etching method according to the embodiment will be described with reference to FIGS. 12 and 13. FIG. 12 is a flowchart illustrating a configuration example of the plasma etching method. FIG. 13 is a sequence chart illustrating a configuration example of the plasma etching method. The plasma etching method can be executed using a plasma processing system that includes any one of the plasma processing apparatuses according to the first to third embodiments. Control such as any following operations, measurements, and commands can be performed using the controller 2.

In a first step ST1, the coolant supply is controlled to supply the coolant to the flow path 120a to maintain the bases 120 and 324, the electrostatic chucks 121 and 325, and the substrate W at −20° C. or lower. When the film to be etched is a silicon-containing film such as a Si film, a SiO₂ film, or a SiN film, the temperature of the substrate W is cooled to −20° C. or lower to perform etching at a high etching rate.

In a second step ST2, the processing gas for etching is started to be supplied from the gas introduction unit into the plasma processing chambers 10 and 310 at a desired pressure and a desired flow rate.

In a third step ST3, the RF signals are supplied from the RF power sources 31 and 341 to the antenna 14 (the first embodiment or the second embodiment) or the upper electrode and the lower electrode (the third embodiment) to generate plasma in the plasma processing chambers 10 and 310. During plasma generation, the bias RF signals are supplied from the RF power sources 31 and 341 to the substrate supports 11 and 311, and etching is started by attraction of ions to the substrate W.

In a fourth step ST4, when the desired etching process for the substrate W is completed in the step ST3, the supply of the processing gas is stopped, and the supply of the bias RF signals is stopped.

In a fifth step ST5, the substrate W is irradiated with light from the light irradiators 50, 201, and 350. The light irradiation may be executed by either continuous irradiation or pulsed irradiation or a combination thereof.

In the continuous irradiation, control is performed such that light is constantly emitted from the light irradiators 50, 201, and 350 during continuation of the step ST5. In such continuous irradiation, the light irradiators 50, 201, and 350 may be controlled to emit light until a temperature of a surface layer of the substrate W becomes 100° C. or higher. In addition, in such continuous irradiation, a time during which all by-products are sublimated and removed may be empirically measured, and the light irradiators 50, 201, and 350 may be controlled to emit light during this time. As an example of the continuous irradiation, in a case where a halogen heater lamp is used as the light source, the time is, for example, 10 seconds. In this case, an intensity of the light emitted from the light source is adjusted such that the temperature of the surface layer of the substrate W reaches a temperature at which the by-products sublimate in 10 seconds.

During the light irradiation, the plasma processing chambers 10 and 310 are exhausted. Accordingly, the sublimated by-products can be exhausted to the outside of the plasma processing chambers 10 and 310.

In a sixth step ST6, it is determined whether to continue plasma etching based on a desired recipe. When plasma etching is to be continued, the process returns to the step ST2 and the steps ST2 to ST6 are executed again. When plasma etching is not to be continued, the process is ended.

In one embodiment, the output from the temperature monitor related to the temperature of the substrate is acquired during execution of the fifth step ST5. At least one of the first temperature of the coolant, the power supplied to the at least one heater, or the intensity of the light with which the substrate on the substrate support is irradiated is adjusted based on the output from the temperature monitor.

In one embodiment, when the substrate support includes a plurality of regions in a plan view and the at least one heater includes a plurality of heaters disposed in the plurality of regions, respectively, the output from the temperature monitor related to the temperature of the substrate is acquired during execution of the fifth step ST5. In addition, based on the output from the temperature monitor, the power supplied to each of the plurality of heaters is adjusted in order to correct the temperature non-uniformity of the substrate on the substrate support caused by light irradiation. That is, when it is detected that temperatures of the regions of the substrate corresponding to the plurality of regions of the substrate support are different, temperatures of the plurality of heaters corresponding to the regions of the substrate are adjusted to correct temperature non-uniformity of the regions of the substrate. The temperature non-uniformity of the regions of the substrate may be corrected by reducing a temperature of a corresponding heater when one region has a temperature higher than a desired temperature, and increasing a temperature of another corresponding heater when another region has a temperature lower than the desired temperature, for example.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

The following configuration examples also fall within the technical scope of the present disclosure.
(1) A plasma processing apparatus including:
a chamber,
a substrate support disposed in the chamber and including a coolant passage,
a dielectric window disposed above the substrate support,
an antenna disposed above the dielectric window,
an RF power source configured to supply an RF signal to the antenna in order to generate plasma in the chamber,
a coolant supply configured to supply a coolant maintained at a first temperature to the coolant passage,
at least one heater disposed in the substrate support,
a heater power source configured to supply power to the at least one heater,
at least one light source configured to temporarily and periodically irradiate a substrate on the substrate support with light to heat the substrate while the plasma is generated in the chamber and while the coolant maintained at the first temperature is supplied to the coolant passage,
a temperature monitor configured to monitor a temperature of the substrate on the substrate support, and
a controller configured to control, based on an output from the temperature monitor, the coolant supply, the heater power source, and/or the at least one light source to adjust the first temperature of the coolant, the power supplied to the at least one heater, and/or an intensity of the light with which the substrate on the substrate support is irradiated.

(2) The plasma processing apparatus according to (1), in which
the first temperature is −20° C. or lower.

(3) The plasma processing apparatus according to (1) or (2), in which
the substrate on the substrate support is etched by the plasma, thereby forming a by-product on the substrate, and
the by-product on the substrate is sublimated by the light.

(4) The plasma processing apparatus according to (3), in which
the substrate on the substrate support is heated to 100° C. or higher by the light.

(5) The plasma processing apparatus according to (4), in which
an irradiation time of the light is 10 seconds or shorter.

(6) The plasma processing apparatus according to (1) or (2), in which
the substrate on the substrate support is etched by the plasma, and
the light promotes an etching reaction.

(7) The plasma processing apparatus according to any one of (1) to (6), in which
the light has a wavelength in a range of 300 nm to 1,100 nm.

(8) The plasma processing apparatus according to any one of (1) to (7), in which
the at least one light source includes a first light source disposed to overlap a central axis of the antenna.

(9) The plasma processing apparatus according to any one of (1) to (7), in which
the at least one light source includes light sources arranged in a peripheral direction along the sidewall of the chamber.

(10) The plasma processing apparatus according to (8), in which
the first light source includes a hemispherical lens.

(11) The plasma processing apparatus according to (9), in which
each of the light sources includes a hemispherical lens.

(12) The plasma processing apparatus according to any one of (7) to (11), in which
the at least one light source includes a halogen heater lamp.

(13) The plasma processing apparatus according to any one of (7) to (11), in which
the at least one light source includes a flash lamp.

(14) The plasma processing apparatus according to any one of (7) to (11), in which
the at least one light source includes an LED.

(15) The plasma processing apparatus according to any one of (1) to (14), in which
the substrate support has regions in a plan view,
the at least one heater includes heaters disposed in the regions, respectively, and
the controller is configured to control, based on the output from the temperature monitor, the heater power source to adjust power supplied to the heaters in order to correct temperature non-uniformity of the substrate on the substrate support caused by irradiation with the light.

(16) The plasma processing apparatus according to any one of (1) to (15), in which
the temperature monitor includes
   a monitor light source configured to emit an electromagnetic wave transmissible through the substrate on the substrate support,
   an emitter configured to obliquely emit the electromagnetic wave generated by the monitor light source to the substrate on the substrate support, and
   a light receiver disposed opposite to the emitter with the substrate interposed therebetween and configured to receive a reflected wave reflected by a front surface and a rear surface of the substrate on the substrate support, and
the controller is configured to determine the temperature of the substrate on the substrate support based on the reflected wave received by the light receiver.

(17) A plasma processing apparatus including:
a chamber,
a substrate support disposed in the chamber and including a coolant passage,
a plasma generator including an RF power source that generates plasma in the chamber,
a coolant supply configured to supply a coolant maintained at a first temperature to the coolant passage in order to cool a substrate on the substrate support, and
at least one light source configured to temporarily and periodically irradiate a substrate on the substrate support with light to heat the substrate while the plasma is generated in the chamber and while the coolant maintained at the first temperature is supplied to the coolant passage.

(18) The plasma processing apparatus according to (17), in which
the first temperature is −20° C. or lower.

(19) The plasma processing apparatus according to (18), in which
the substrate on the substrate support is etched by the plasma, thereby forming a by-product on the substrate, and
the by-product on the substrate is sublimated by the light.

(20) The plasma processing apparatus according to (19), in which
an irradiation time of the light is 10 seconds or shorter.

(21) The plasma processing apparatus according to any one of (17) to (20), in which
the light has a wavelength in a range of 300 nm to 1,100 nm.

(22) The plasma processing apparatus according to (21), in which
the at least one light source includes light sources arranged in a peripheral direction along the sidewall of the chamber.

(23) A plasma etching method including:
placing a substrate on a substrate support in a chamber,
generating plasma in the chamber to perform plasma etching on the substrate,
controlling a coolant supply that supplies a coolant to a coolant passage in the substrate support, while the plasma etching is performed, to maintain the substrate at −20° C. or lower, and
controlling a light irradiator to irradiate the substrate with light, while the plasma etching is performed and while the substrate is maintained at −20° C. or lower, to temporarily and periodically heat the substrate.

### REFERENCE SIGNS LIST

1, 200, 300 plasma processing apparatus
2 controller
10, 310 plasma processing chamber
11, 311 substrate support
14 antenna
31, 341 RF power source
50, 201, 350 light irradiator
51, 202, 351 light source
100 optical interference system
101 dielectric window
W substrate

1. A plasma processing apparatus comprising:
a chamber;
a substrate support disposed in the chamber and including a coolant passage;
a dielectric window disposed above the substrate support;
an antenna disposed above the dielectric window;
an RF power source configured to supply an RF signal to the antenna in order to generate plasma in the chamber;
a coolant supply configured to supply a coolant maintained at a first temperature to the coolant passage;
at least one heater disposed in the substrate support;
a heater power source configured to supply power to the at least one heater;
at least one window provided at a sidewall of the chamber;
at least one light source configured to temporarily and periodically irradiate a substrate on the substrate support with light through the at least one window to heat the substrate while the plasma is generated in the chamber and while the coolant maintained at the first temperature is supplied to the coolant passage;
a temperature monitor configured to monitor a temperature of the substrate on the substrate support, and
processing circuitry configured to control, based on an output from the temperature monitor, the coolant supply, the heater power source, and/or the at least one light source to adjust the first temperature of the coolant, the power supplied to the at least one heater, and/or an intensity of the light with which the substrate on the substrate support is irradiated.

2. The plasma processing apparatus according to claim 1, wherein
the first temperature is −20° C. or lower.

3. The plasma processing apparatus according to claim 1, wherein
the substrate on the substrate support is etched by the plasma, thereby forming a by-product on the substrate, and
the by-product on the substrate is sublimated by the light.

4. The plasma processing apparatus according to claim 3, wherein
the substrate on the substrate support is heated to 100° C. or higher by the light.

5. The plasma processing apparatus according to claim 4, wherein
an irradiation time of the light is 10 seconds or shorter.

6. The plasma processing apparatus according to claim 1, wherein
the substrate on the substrate support is etched by the plasma, and
the light promotes an etching reaction.

7. The plasma processing apparatus according to claim 1, wherein
the light has a wavelength in a range of 300 nm to 1,100 nm.

8. The plasma processing apparatus according to claim 7, further comprising:
a first light source disposed to overlap a central axis of the antenna, in addition to the at least one light source.

9. The plasma processing apparatus according to claim 8, wherein
the first light source includes a hemispherical lens.

10. The plasma processing apparatus according to claim 7, wherein
the at least one light source includes light sources arranged in a peripheral direction along the sidewall of the chamber.

11. The plasma processing apparatus according to claim 10, wherein
each of the light sources includes a hemispherical lens.

12. The plasma processing apparatus according to claim 7, wherein
the at least one light source includes a halogen heater lamp, a flash lamp or an LED.

13. The plasma processing apparatus according to claim 1, wherein
the substrate support has regions in a plan view,
the at least one heater includes heaters disposed in the regions, respectively, and
the processing circuitry is configured to control, based on the output from the temperature monitor, the heater power source to adjust power supplied to the heaters in order to correct temperature non-uniformity of the substrate on the substrate support caused by irradiation with the light.

14. The plasma processing apparatus according to claim 1, wherein
the temperature monitor includes
a monitor light source configured to emit an electromagnetic wave transmissible through the substrate on the substrate support,
an emitter configured to obliquely emit the electromagnetic wave generated by the monitor light source to the substrate on the substrate support, and
a light receiver disposed opposite to the emitter with the substrate interposed therebetween and configured to receive a reflected wave reflected by a front surface and a rear surface of the substrate on the substrate support, and
the processing circuitry is configured to determine the temperature of the substrate on the substrate support based on the reflected wave received by the light receiver.

15. A plasma processing apparatus comprising:
a chamber;
a substrate support disposed in the chamber and including a coolant passage;
a plasma generator including an RF power source that generates plasma in the chamber;
a coolant supply configured to supply a coolant maintained at a first temperature to the coolant passage in order to cool a substrate on the substrate support;
at least one window provided at a sidewall of the chamber; and
at least one light source configured to temporarily and periodically irradiate a substrate on the substrate support with light through the at least one window to heat the substrate while the plasma is generated in the chamber and while the coolant maintained at the first temperature is supplied to the coolant passage.

16. The plasma processing apparatus according to claim 15, wherein
the first temperature is −20° C. or lower.

17. The plasma processing apparatus according to claim 16, wherein
the substrate on the substrate support is etched by the plasma, thereby forming a by-product on the substrate, and
the by-product on the substrate is sublimated by the light.

18. The plasma processing apparatus according to claim 17, wherein
an irradiation time of the light is 10 seconds or shorter, and
the light has a wavelength in a range of 300 nm to 1,100 nm.

19. The plasma processing apparatus according to claim 18, wherein
the at least one light source includes light sources arranged in a peripheral direction along the sidewall of the chamber.

20. A plasma etching method comprising:
placing a substrate on a substrate support in a chamber,
generating plasma in the chamber to perform plasma etching on the substrate,
controlling a coolant supply that supplies a coolant to a coolant passage in the substrate support, while the plasma etching is performed, to maintain the substrate at −20° C. or lower, and
controlling a light irradiator to irradiate the substrate with light, while the plasma etching is performed and while the substrate is maintained at −20° C. or lower, to temporarily and periodically heat the substrate.
